(19) United States
(12) Patent Application Publication
(10) Pub. No.: US 2010/0018576 A1
(43) Pub. Date: Jan. 28, 2010

(54) SOLAR CELL

(76) Inventors: Bumsung KIM, Seoul (KR); Sunhee Kim, Seoul (KR); Hwanyeon Kim, Seoul (KR); Juhwan Yun, Seoul (KR)

Correspondence Address: BIRCH STEWART KOLASCH & BIRCH, PO BOX 747, FALLS CHURCH, VA, 22040-0747, US

(21) Appl. No.: 12/507,595

(22) Filed: Jul. 22, 2009

(30) Foreign Application Priority Data
Jul. 23, 2008 (KR) 10-2008-0071450

(51) Int. Cl. H01L 31/0236

(52) U.S. Cl. 136/256

(57) ABSTRACT

A solar cell is disclosed. The solar cell includes a semiconductor substrate on which a p-n junction is formed, a first electrode contacting a first conductive type semiconductor of the semiconductor substrate, a second electrode contacting a semiconductor of a second conductive type opposite the first conductive type, a plurality of first projections on a light receiving surface of the semiconductor substrate, and at least one second projection inside each of the plurality of first projections. A height of the second projection is less than a height of the first projection.

This application claims the benefit of Korea Patent Application No. 10-2008-0071450 filed on Jul. 23, 2008, the entire contents of which is incorporated herein by reference for all purposes as if fully set forth herein.

### BACKGROUND

1. Field

Embodiments of the invention relate to a solar cell.

2. Description of the Related Art

A solar cell generally includes a substrate and an emitter layer, formed of a semiconductor, each having a different conductive type such as a p-type and an n-type, and electrodes respectively formed on the substrate and the emitter layer. A p-n junction is formed at an interface between the substrate and the emitter layer.

When light is incident on the solar cell, a plurality of electron-hole pairs are generated in the semiconductor. Each of the electron-hole pairs is separated into electrons and holes by the photovoltaic effect. Thus, the separated electrons move to the n-type semiconductor (e.g., the emitter layer) and the separated holes move to the p-type semiconductor (e.g., the substrate), and then the electrons and holes are collected by the electrodes electrically connected to the emitter layer and the substrate, respectively. The electrodes are connected to each other using electric wires to thereby obtain an electric power.

As above, the solar cell converts light energy into electrical energy. A reflectance of light incident on the semiconductor has to be reduced so as to improve a conversion efficiency of the solar cell. Thus, a texturing process has been performed on the surface of the semiconductor.

### SUMMARY

Embodiments of the invention provide a solar cell capable of improving an operation efficiency.

In one aspect, there is a solar cell comprising a semiconductor substrate on which a p-n junction is formed, a first electrode contacting a first conductive type semiconductor of the semiconductor substrate, a second electrode contacting a semiconductor of a second conductive type opposite the first conductive type, a plurality of first projections on a light receiving surface of the semiconductor substrate, and at least one second projection inside each of the plurality of first projections, a height of the second projection being less than a height of the first projection.

The plurality of first projections may be positioned on the semiconductor substrate to be spaced apart from one another at a constant distance. The first projection may surround the second projection.

Each of the first projections may have at least one flat top surface or at least one peaked top surface.

A shape of the first projection when viewed from the light receiving surface of the semiconductor substrate may be a rectangle. The rectangular first projection may have at least one curved corner.

A shape of the first projection when viewed from the light receiving surface of the semiconductor substrate may be a circle.

Further scope of applicability of the invention will become apparent from the detailed description given hereinafter. However, it should be understood that the detailed description and specific examples, while indicating embodiments of the invention, are given by illustration only, since various changes and modifications within the spirit and scope of the invention will become apparent to those skilled in the art from this detailed description.

### BRIEF DESCRIPTION OF THE DRAWINGS

The accompany drawings, which are included to provide a further understanding of the invention and are incorporated on and constitute a part of this specification, illustrate embodiments of the invention and together with the description serve to explain the principles of the invention. In the drawings:

FIG. 1 is a perspective view of a substrate for solar cell having a processed surface according to a first exemplary embodiment of the invention;

FIG. 2 is a cross-sectional view taken along line I-I of FIG. 1;

FIG. 3 is a perspective view of a substrate for solar cell having a processed surface according to a second exemplary embodiment of the invention;

FIG. 4 is a cross-sectional view taken along line II-II of FIG. 3;

FIGS. 5 to 8 illustrate a substrate for solar cell having a processed surface according to another exemplary embodiment of the invention; and

FIG. 9 illustrates a solar cell including a substrate whose a surface is processed according to an exemplary embodiment of the invention.

### DETAILED DESCRIPTION OF THE EMBODIMENTS

Reference will now be made in detail embodiments of the invention examples of which are illustrated in the accompanying drawings.

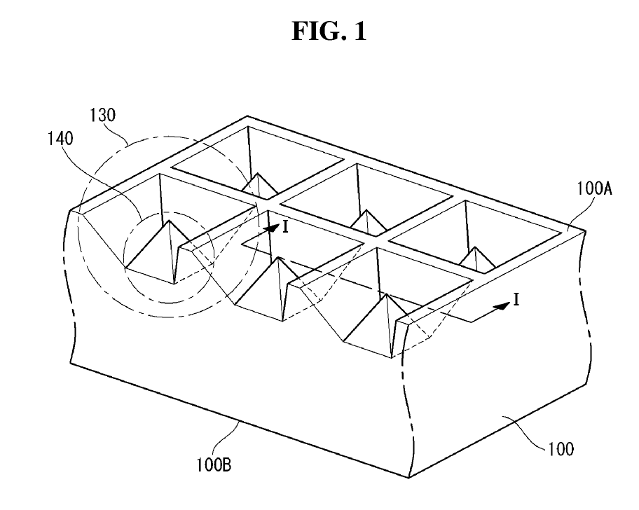

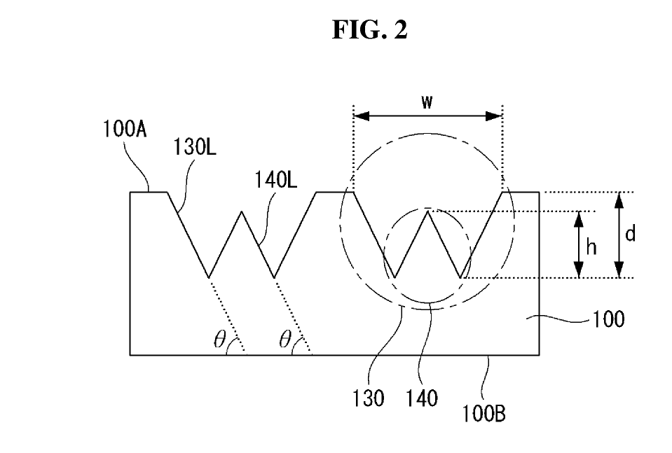

FIG. 1 is a perspective view of a substrate for solar cell having a processed surface according to a first exemplary embodiment of the invention. FIG. 2 is a cross-sectional view taken along line I-I of FIG. 1.

As shown in FIG. 1, a plurality of first projections 130 are positioned on a light receiving surface 100A of a substrate 100 to be spaced apart from one another at a constant distance, and a second projection 140 is formed inside each of the plurality of first projections 130. Hence, a size of a scattering surface of the substrate 100 scattering solar light from the outside increases. Further, an amount of light reflected from the substrate 100 among the incident solar light decreases, and a conversion efficiency of the solar cell increases.

As shown in FIG. 1, each of the first projections 130 has a depressed inner portion, and the second projection 140 is positioned in the depressed inner portion of each first projection 130. In other words, the first projection 130 surrounds the second projection 140.

If the first projection 130 is formed through a photolithography process using a photomask, the first projection 130 may be formed using an anisotropic etching method. An etch rate in the anisotropic etching method varies depending on a crystal orientation of a substrate. In the embodiment, an anisotropic etching process is performed on the substrate 100 formed of silicon. Each of the first projections 130 has at least one flat top surface.

Because an etch rate of (111)-oriented of silicon is different from an etch rate of (100)-oriented of silicon, the first projection 130 has an inclined side 130L as shown in FIG. 2.

In this case, because the first projection 130 and the second projection 140 are simultaneously formed through the anisotropic etching process, an angle θ between the inclined side 130L of the first projection 130 and a bottom surface 100B of the substrate 100 is equal to an angle θ between a inclined side 140L of the second projection 140 and the bottom surface 100B of the substrate 100 when the substrate 100 is formed of silicon. In addition, the angle θ is approximately 54.76°. As above, when the first projection 130 and the second projection 140 are simultaneously formed through the anisotropic etching process, the manufacturing cost and the manufacturing time can be reduced.

The anisotropic etching may include a wet etching, a dry etching, or a mechanical etching, etc. In case of the wet etching, an etchant including NaOH, KOH, H₂O, and isopropyl alcohol or tetramethylammonium hydroxide (TMAH) may be used. In case of the dry etching, plasma into which CHF₃ gas or SF₆ gas is injected may be used. In case of the mechanical etching, the first projection 130 having the inclined side 130L may be formed using a laser.

The first projection 130 may be formed through a screen printing process, an inkjet printing process, etc. other than the photolithography process.

As shown in FIG. 2, when the first projection 130 and the second projection 140 are formed on the substrate 100, a height d of the first projection 130 is greater than a height h of the second projection 140. The height d of the first projection 130 and the height h of the second projection 140 are measured from the light receiving surface 100A of the substrate 100.

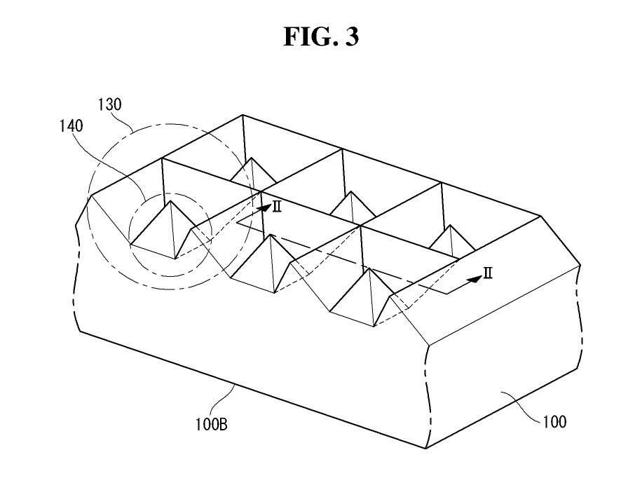

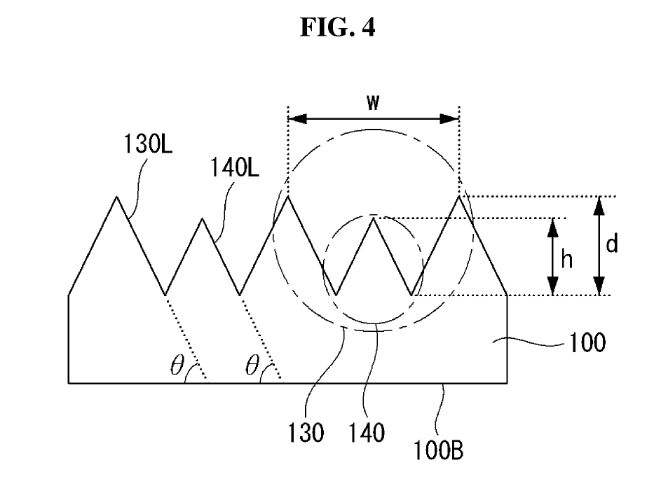

FIG. 3 is a perspective view of a substrate for solar cell having a processed surface according to a second exemplary embodiment of the invention. FIG. 4 is a cross-sectional view taken along line II-II of FIG. 3.

As shown in FIG. 3, a plurality of first projections 130 are positioned on a light receiving surface 100A of a substrate 100 to be spaced apart from one another at a constant distance, and a second projection 140 is formed inside each of the plurality of first projections 130. Hence, a size of a scattering surface of the substrate scattering solar light from the outside increases. Further, an amount of light reflected from the substrate 100 among the incident solar light decreases, and a conversion efficiency of the solar cell increases.

As shown in FIG. 3, each of the first projections 130 has a depressed inner portion, and the second projection 140 is positioned in the depressed inner portion of each first projection 130. In other words, the first projection 130 surrounds the second projection 140.

Unlike the first exemplary embodiment illustrated in FIGS. 1 and 2, each of the first projections 130 in the second exemplary embodiment has at least one peaked top surface.

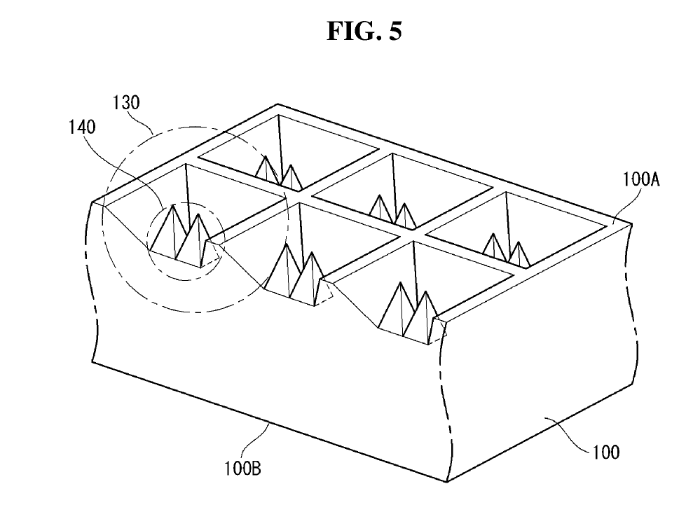

FIGS. 5 to 8 illustrate a substrate for solar cell having a processed surface according to another exemplary embodiment of the invention.

While one second projection 140 is formed inside each of the first projections 130 in the first and second exemplary embodiments, a plurality of second projections 140 may be formed inside each of a plurality of first projections 130 in a third exemplary embodiment illustrated in FIG. 5.

As above, when the plurality of second projections 140 are formed inside each of the plurality of first projections 130, scattered solar light among incident solar light increases. Hence, a conversion efficiency of the solar cell further increases.

In the substrate for solar cell having the processed surface according to the first to third exemplary embodiments, each of the first projections 130 when viewed from the light receiving surface 100A of the substrate 100 may have a rectangular shape.

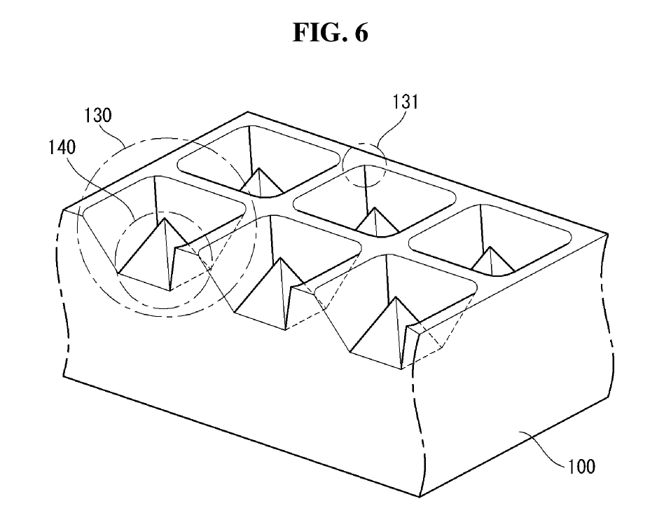

Furthermore, as shown in FIG. 6, in a substrate for solar cell having a processed surface according to a fourth exemplary embodiment, each of a plurality of rectangular first projections 130 may have at least one curved corner 131.

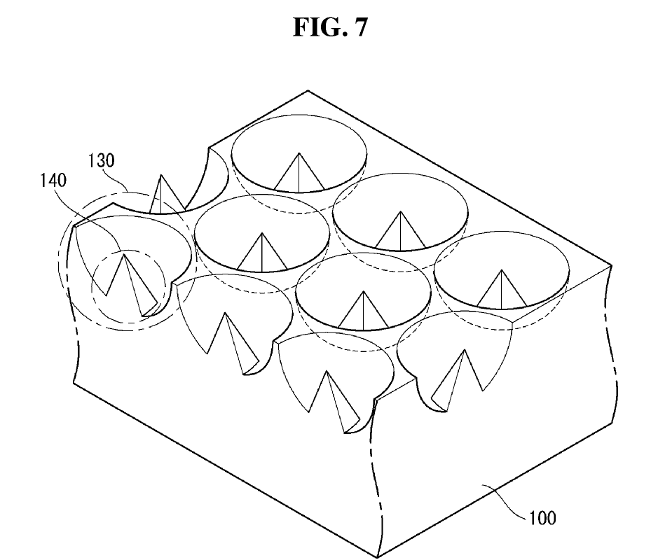

Further, as shown in FIG. 7, in a substrate for solar cell having a processed surface according to a fifth exemplary embodiment, each of a plurality of first projections 130 when viewed from the light receiving surface 100A of the substrate 100 may have a circle shape.

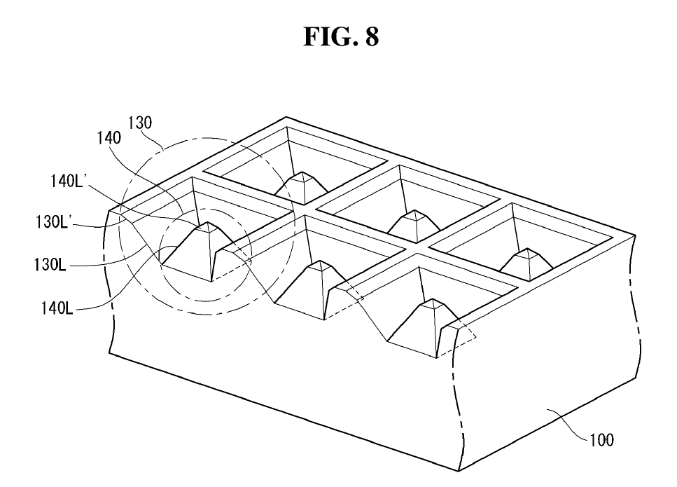

As shown in FIG. 8, in a substrate for solar cell having a processed surface according to a sixth exemplary embodiment, a side 130L′ of each of first projections 130 and a side 140L′ of each of second projections 140 are bent at different angles. As above, when the side 130L′ of each of the first projections 130 and the side 140L′ of each of the second projections 140 are bent, a size of a scattering surface of a substrate 100 increases and an amount of light reflected from the substrate 100 decreases. Hence, a conversion efficiency of the solar cell increases.

In the substrate for solar cell having the processed surface according to the sixth exemplary embodiment illustrated in FIG. 8, an anisotropic etching process is performed on the substrate 100 for a predetermined period of time to form the first and second projections 130 and 140 in the same manner as FIG. 1, Then, an isotropic etching process is performed on the first and second projections 130 and 140 for a period of time shorter than the predetermined period of time required in the anisotropic etching process to form the first and second projections 130 and 140 respectively having the sides 130L′ and 140L′. In this case, slopes of the sides 130L and 140L of FIG. 1 formed through the anisotropic etching process are different from slopes of the sides 130L′ and 140L′, respectively.

The isotropic etching process may use the same etchant as the anisotropic etching process. A concentration of the etchant used in the isotropic etching process is greater than a concentration of the etchant used in the anisotropic etching process. As above, the concentration of the etchant used in the isotropic etching process is higher than the concentration of the etchant used in the anisotropic etching process, time required in the isotropic etching process is shorter than time required in the anisotropic etching process. If time required in the isotropic etching process is longer than time required in the anisotropic etching process, an amount of reflected light increases because of the excessive isotropic etching.

As above, when the isotropic etching process is performed subsequent to the anisotropic etching process, an end of the first projection 130 and an end of the second projection 140 are isotropically etched. Therefore, slopes of the sides 130L′ and 140L′ of the isotropically etched first and second projections 130 and 140 are different from slopes of the sides 130L and 140L of the anisotropically etched first and second projections 130 and 140, respectively.

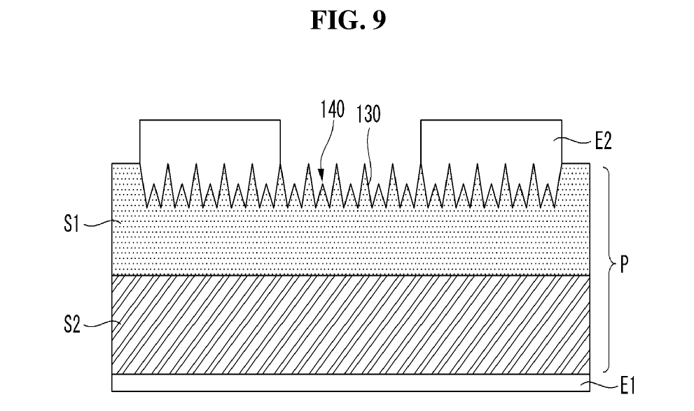

FIG. 9 illustrates a solar cell including a substrate, whose a surface is processed, according to an exemplary embodiment of the invention. As shown in FIG. 9, the solar cell includes a semiconductor substrate P, a plurality of first electrodes E1, and a plurality of second electrodes E2.

The semiconductor substrate P is doped using an impurity diffusion method or an ion implantation method, and thus a p-n junction of a p-type semiconductor and an n-type semiconductor is generated in the semiconductor substrate P. In FIG. 9, a boundary between a first semiconductor S1 and a second semiconductor S2 is the p-n junction. The first electrode E1 contacts a first conductive type semiconductor of the semiconductor substrate P. In the embodiment, the first conductive type semiconductor may be a p-type semiconductor or an n-type semiconductor.

The second electrode E2 contacts a second conductive type semiconductor having a conductive type opposite a conductive type of the first conductive type semiconductor contacting the first electrode E1. For example, if the first electrode E1 contacts the n-type semiconductor of the semiconductor substrate P, the second electrode E2 contacts the p-type semiconductor of the semiconductor substrate P. Alternatively, if the first electrode E1 contacts the p-type semiconductor of the semiconductor substrate P, the second electrode E2 contacts the n-type semiconductor of the semiconductor substrate P.

The second electrode E2 may be formed of a transparent material, such as indium tin oxide (ITO) capable of transmitting solar light.

As described above, a plurality of first projections 130 are formed in an area of the semiconductor substrate P between the second electrodes E2, and a second projection 140, whose a height is less than a height of the first projection 130, is formed inside each of the first projections 130.

Solar light scattered by the first and second projections 130 and 140 among solar light from the outside generates the photovoltaic effect, and thus electrons and holes of the n-type semiconductor and the p-type semiconductor move to and the first electrode E1 and the second electrodes E2 to thereby generate an electric power. In this case, the first and second projections 130 and 140 increase an amount of scattered solar light, and a conversion efficiency of the solar cell increases.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell comprising:
a semiconductor substrate on which a p-n junction is formed;
a first electrode contacting a first conductive type semiconductor of the semiconductor substrate;
a second electrode contacting a semiconductor of a second conductive type opposite the first conductive type;
a plurality of first projections on a light receiving surface of the semiconductor substrate; and
at least one second projection inside each of the plurality of first projections, a height of the second projection being less than a height of the first projection.

2. The solar cell of claim 1, wherein the plurality of first projections are positioned on the semiconductor substrate to be spaced apart from one another at a constant distance.

3. The solar cell of claim 1, wherein the first projection surrounds the second projection.

4. The solar cell of claim 1, wherein each of the first projections has at least one flat top surface.

5. The solar cell of claim 1, wherein each of the first projections has at least one peaked top surface.

6. The solar cell of claim 1, wherein a shape of the first projection when viewed from the light receiving surface of the semiconductor substrate is a rectangle.

7. The solar cell of claim 6, wherein the rectangular first projection has at least one curved corner.

8. The solar cell of claim 1, wherein a shape of the first projection when viewed from the light receiving surface of the semiconductor substrate is a circle.
